(19) United States
(12) Patent Application Publication
(10) Pub. No.: US 2019/0096629 A1
(43) Pub. Date: Mar. 28, 2019

(54) A CORRECTOR STRUCTURE AND A METHOD FOR CORRECTING ABERRATION OF AN ANNULAR FOCUSED CHARGED-PARTICLE BEAM

(71) Applicant: NATIONAL UNIVERSITY OF SINGAPORE, Singapore (SG)

(72) Inventor: Anjam KHURSHEED, Singapore (SG)

(73) Assignee: NATIONAL UNIVERSITY OF SINGAPORE, Singapore (SG)

(21) Appl. No.: 16/097,479

(22) PCT Filed: May 5, 2017
(86) PCT No.: PCT/SG2017/050235

§ 371 Date: Oct. 29, 2018

(30) Foreign Application Priority Data
May 6, 2016 (SG) 10201603595Q

(51) Int. Cl. H01J 37/153

(52) U.S. Cl. CPC H01J 37/153; H01J 2237/1534; H01J 2237/0492; H01J 2237/10

(57) ABSTRACT

A corrector structure and a method for correcting aberration of an annular focused charged-particle beam, the corrector structure comprising a plurality of lenses configured for reducing second-order geometric aberration in the charged-particle beam.

### FIELD OF INVENTION

The present invention relates broadly to a corrector structure and a method for correcting aberration of an annular focused charged-particle beam.

### BACKGROUND

Geometric aberration correction is typically applied in conventional scanning electron or ion focused probe microscopes such as the scanning electron microscope (SEM) or the scanning transmission electron microscope (STEM). In one class of aberration correctors, the correctors function with annular focused beam optics. Unlike charged particle beam optics in which electrons or ions are confined to a central circular region that encloses the rotational axis of symmetry of an objective lens, as shown in FIG. 1a, in annular focused beam optics, electrons or ions travel off-axis through a ring region defined by an annular aperture, leaving the central axis region free of the beam, as shown in FIG. 1b. This makes it possible to correct for lens aberrations by placing an electrode on the axis since it is now a beam free region.

Annular focused electron beam columns have been designed for a variety of different applications. In the category of geometrical aberration correctors for an electron microscope, Lenz and Wilska proposed an electrostatic corrector unit placed in an objective lens's pole-piece gap [1]. This corrector unit took the form of a single co-axial cable geometry limited to first-order aberration correction, where a single inner electrode placed on the lens axis is surrounded by an outer tube shaped electrode. This type of lens was later referred to as a core-lens and applied to form an objective lens that had a circular array of pencil axes located off-axis for 3D imaging [2,3]. Unlike the single rotational axis of a conventional electron microscope column, each pencil ray had its own separate curvilinear optical axis.

Ito et al proposed a variation of the Lenz and Wilska geometric aberration core-lens corrector, where the inner and outer electrodes have needle/cone shapes [4]. They presented a series of conceptual designs of how core-lenses might correct for objective lens aberrations, however, no quantitative analysis was presented, and no discussion about the degree to which aberrations could be corrected was carried out. A quantitative analysis of a column made from core-lenses was presented later by Takaoka, Nishi and Ito [5]. They provided simulations to predict that a series of core lenses can minimise both geometric and chromatic aberrations, however, their column design was not practical. They generated the field distribution of a core-lens from a group of four charges located off-axis, instead of using an on-axis electrode. The semi-angle from the point-source in their design was the same as the final semi-angle, giving it unity demagnification. Moreover, they did not use any conventional objective lens in their design, their groups of charges acted together as a single, aberration minimized focusing lens of unit demagnification.

Khursheed described an on-axis electrode electric core-lens unit acting to correct for the geometrical aberrations of an column whose annular beam is produced by an idealised ring-cathode electron source [6]. Khursheed and Ang later applied this core-lens design to correct for the chromatic and geometric aberrations of a conventional electron microscope column in which the hole-aperture is replaced by an annular aperture, and they showed the correction of annular geometric correction [7].

At present, geometric aberration still prevents the use of large current (with large apertures) and long working distances for focused charged-particle beams.

Embodiments of the present invention seek to provide a corrector structure and a method for correcting aberration of an annular focused charged-particle beam for reducing 2^{nd} order geometric aberration.

### SUMMARY

In accordance with a first aspect of the present invention, there is provided a corrector structure for correcting aberration of an annular focused charged-particle beam, the corrector structure comprising a plurality of lenses configured for reducing second-order geometric aberration in the charged-particle beam.

In accordance with a second aspect of the present invention, there is provided method for correcting aberration of an annular focused charged-particle beam, the method comprising providing a plurality of lenses; and configuring the lenses for reducing second-order geometric aberration in the charged-particle beam.

In accordance with a third aspect of the present invention, there is provided a column for focusing a charged particle beam, comprising the corrector structure of the first aspect.

### BRIEF DESCRIPTION OF THE DRAWINGS

Embodiments of the invention will be better understood and readily apparent to one of ordinary skill in the art from the following written description, by way of example only, and in conjunction with the drawings, in which:

FIG. 1a) shows a schematic diagram of circular focused charged particle beams.

FIG. 1b) shows a schematic diagram of annular focused charged particle beams.

FIG. 2a) shows a graph illustrating geometric aberration effect caused by an objective lens.

FIG. 2b) shows a graph illustrating geometric aberration effect caused by an electric objective lens when using a hole aperture.

FIG. 2c) shows a graph illustrating geometric aberration effect caused by an electric objective lens using an annular aperture.

FIG. 3 shows a graph illustrating an ideal corrector action for an annular focusing electric objective lens, according to an example embodiment.

FIG. 4a) shows a schematic diagram illustrating geometric aberration effect caused by a converging core-lens.

FIG. 4b) shows a graph illustrating the form a the radial force-distribution in a converging core-lens.

FIG. 4c) shows a graph illustrating source position shift as a function of semi-angular spread caused by a converging core-lens.

FIG. 5a) shows a schematic diagram illustrating geometric aberration effect caused by a diverging core-lens.

FIG. 5b) shows a graph illustrating the form a the radial force-distribution in a diverging core-lens.

FIG. 5c) shows a graph illustrating source position shift as a function of semi-angular spread caused by a diverging core-lens.

FIG. 6a) shows a schematic diagram illustrating a corrector structure consisting of three core lenses that compensates for the geometric aberration of an objective lens, according to an example embodiment.

FIG. 6b) shows a graph illustrating the individual and combined source position shift as a function of semi-angular spread caused by the corrector structure of FIG. 6a), according to an example embodiment.

FIG. 7a) shows the equipotential lines on three core-lenses of a corrector structure, according to an example embodiment.

FIG. 7b) shows the equipotential lines on an example electric objective lens to be corrected according to an example embodiment.

FIG. 8 shows a direct ray tracing graph at second order geometric aberration correction condition for a 10 kV electric Einzel objective lens test example, according to an example embodiment.

FIG. 9 shows a graph illustrating simulated probe size as a function of final angular spread for the electric Einzel objective lens test example of FIG. 8, according to an example embodiment.

FIG. 10 shows a graph illustrating comparative simulated probe size data for an uncorrected circular beam and a second order geometric aberration corrected annular beam having the same current for the Einzel lens test example, according to an example embodiment. The radii for the apertures are R0=75.65 μm for the circular aperture and R1=132.77 μm and R2=152.81 μm for the annular aperture. The RMS probe radii are 97 nm and 2 nm respectively for the uncorrected circular beam and annular beam corrected cases.

FIG. 11 shows a graph illustrating comparative simulated probe size data of first-order annular beam correction and second-order annular beam correction for the Einzel lens test example, according to an example embodiment.

FIG. 12 shows a flow chart illustrating a method for correcting aberration of an annular focused charged-particle beam, according to an example embodiment.

### DETAILED DESCRIPTION

The example embodiments described herein are designed to reduce the annular geometric aberrations caused by a conventional objective lens to second-order, so as to advantageously further reduce the size of the final spot size of the charged particle beam. For the same probe current, the final geometric aberration limited spot size from example embodiments is predicted to be around a factor of 50 times smaller than the case where a hole-aperture is used with the same objective lens for the same probe current, and over one order of magnitude better than that possible with first-order correction when using a annular aperture for the same probe current.

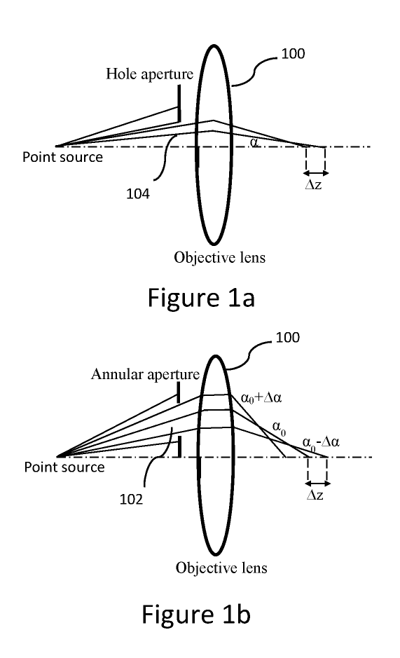

Geometric aberrations are a function of the beam semi-angle, a in the case of a hole-aperture beam, and α₀±Δα in the case of an annular focused beam, as shown in FIGS. 1a) and b) respectively. In both cases, the objective lens 100 will act to provide a stronger focusing action on the wider-angle rays than the smaller-angle rays. This is because the objective lens' 100 field strength increases as a function of radius.

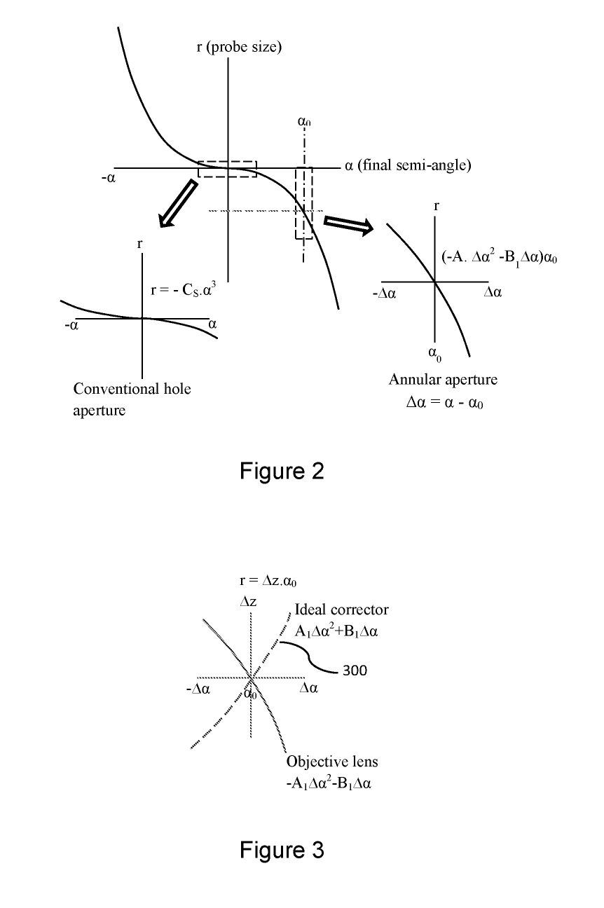

In general, for the same angular spread, the final spot size formed by an objective lens for the annular beam (FIG. 1 b) will be orders of magnitude higher than that of its conventional circular beam counterpart (FIG. 1a). This is because particle rays in the annular beam 102 travel much further off-axis than for the circular beam 104, in a region where the geometric aberration varies much more steeply than it does near the axis, as shown in FIGS. 2 a) to c). The geometric aberration radius for the circular beam is characterised by third-order variations with respect to the beam angular spread (see FIG. 2b), whereas the inventors have recognized that in the case of the annular shaped beam, the variations are dominated by first-order and second-order terms see FIG. 2c). According to example embodiments, the situation can be greatly improved by the use of a core-lens system where a central electrode is placed on the rotational axis of symmetry. FIG. 3 shows the anti-symmetric aberration characteristics of the objective lens (curve 300), the ideal geometrical aberration characteristics for a corrector unit according to an example embodiment (up to second-order).

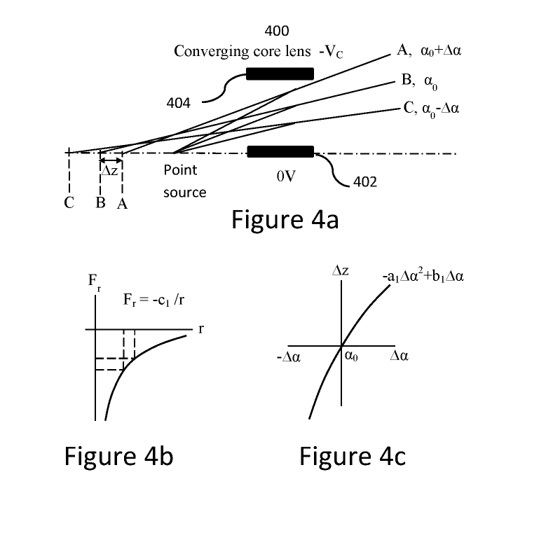

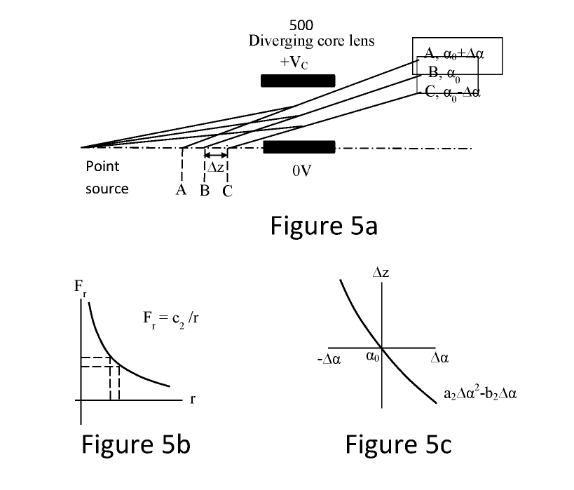

FIG. 4a) depicts the focusing action of a simple electric co-axial cable type of core-lens 400 geometry, where a zero-voltage on-axis electrode 402 is surrounded by a cylindrical conductor 404 that is biased to a negative voltage. The strength of the electric radial force, Fᵣ, follows the usual (1/r) dependence and is negative (see FIG. 4b), which in turn produces a similar such graph for the virtual source positional shift (Δz) as a function of semi-angle (see FIG. 4c). This is because the change in angle experienced by a charged particle ray as it travels through the core-lens 400 is, to the first-approximation, directly proportional to the radial force strength (Fᵣ), and this projects directly back into a positional shift from where the ray appears to originate (Δz). This aberration characteristic of the converging core-lens 400 has the correct first-order component (positive, i.e. +b₁) as the ideal corrector action shown in FIG. 3, but the wrong second-order component/curvature (negative, i.e. −a₁). On the other hand, a diverging core-lens 500 has the opposite property: a correct, positive curvature (second-order term), i.e. +a₂, but the wrong first-order term (negative, i.e. −b₂), as shown in FIGS. 5a) to c).

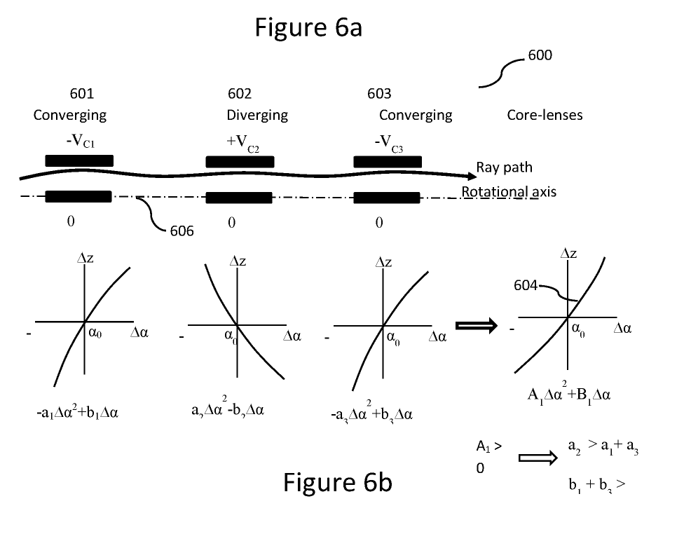

FIG. 6a) presents a system 600 of three core-lenses 601 to 603 according to an example embodiment, which when combined can advantageously generate the ideal corrector focusing action shown in FIG. 3. The strengths of the three core lenses 601 to 603 are adjusted according to this example embodiment so that the final aberration characteristic 604 has both positive first-order and second-order terms, i.e. +A₁ and +B₁, as shown in FIG. 6b). This is found to be possible because the first-derivative of the radial force distribution (proportional to (1/r²)) varies less sharply than its second-derivative (proportional to (1/r³) and opposite in sign). The first core lens 601 deflects the ray closer to the axis 606, and at the smaller radius it experiences the diverging radial force of the second-core lens 602, which directs the ray back out to a larger radius, where upon it experiences the converging action of the third core-lens 603. If the voltages on the core-lenses 601 to 603 are scaled suitably, both positive first-order and second-order terms (curvature) of the geometric aberration characteristic 604 can preferably be obtained, which can be chosen to cancel or at least reduce the corresponding negative first-order and second-order terms of an objective lens (not shown).

It was found that a minimum of three lenses are believed to be required for an incoming diverging charged-particle beam (i.e. where the beam diverges from its source, as is typically the case with e.g. most electron sources). For an incoming converging charged-particle beam, it was found to be in principle possible to use only two lenses. Accordingly, in different embodiments two, three or more lenses may be used.

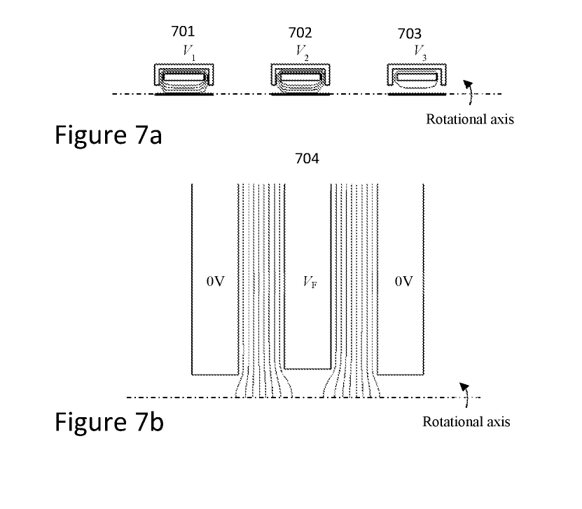

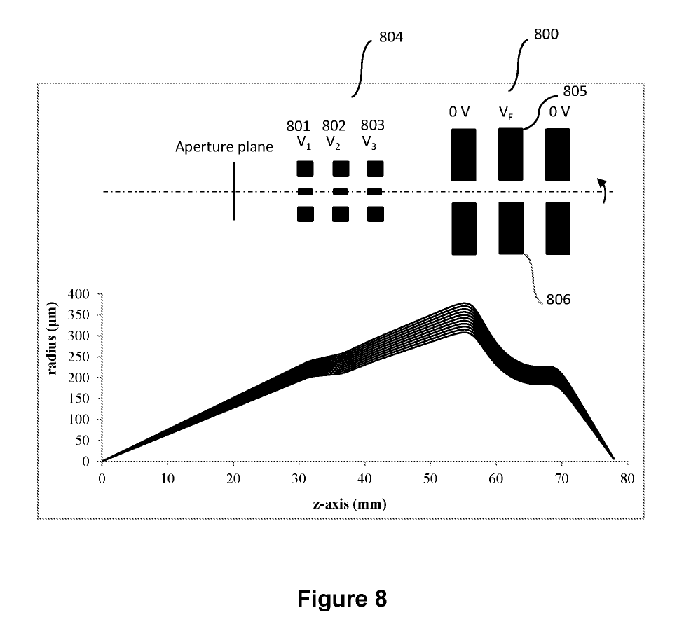

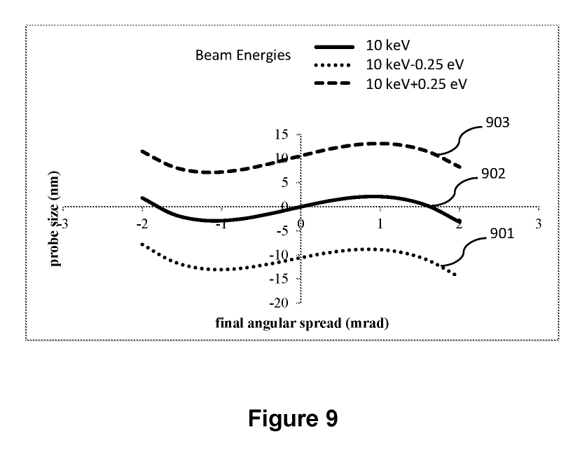

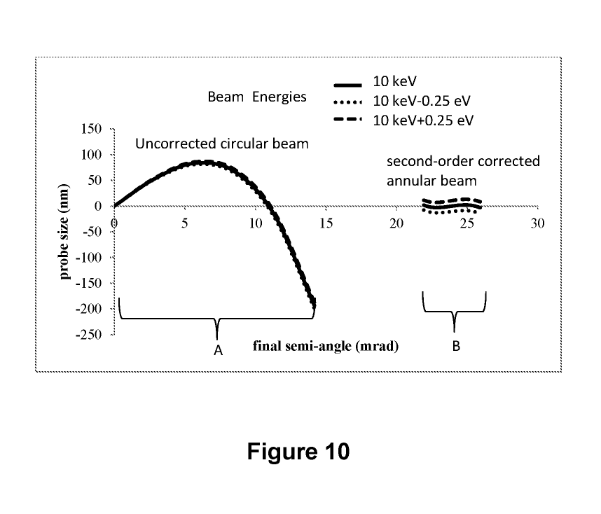

FIGS. 7a) and b) show the equipotential lines of numerically solved electric field distributions for a series of three electric coaxial core-lenses 701-703 and a simple electric Einzel objective lens 704, respectively. These potential field distributions were solved by the use of the commercial Lorentz 2EM boundary element software [8]. FIG. 8 shows direct ray tracing of 10 keV electrons leaving an ideal source point from a range of different angles being focused by the test Einzel objective lens 800 to a working distance of 5.25 mm. The voltages on the outer plates of the three core-lenses 801 to 803 of the corrector structure 804 were systematically varied according to an example embodiment to arrive at the first-order and second-order corrected geometric aberration conditions. In each case, the voltage on the Einzel lens middle electrodes 805, 806 was readjusted to maintain the 5.25 mm working distance as the core-lenses 801 to 803 voltages were varied. The simulated rays shown in FIG. 8 are plot for the second-order geometric aberration corrected condition according to an example embodiment, where the voltages on the lens electrodes were found to be, V₁=−37 V, V₂=37 V and V₃=−7.38 V, and V_{F}=29.3 kV. The simulated probe size as a function of final angular spread for the three different energies of 10 keV, 10 keV-0.25 eV, and 10 keV+0.25 eV is shown in FIG. 9 (curves 901 to 903, respectively), noting that an energy spread of this kind is typically characteristic of the Schottky field emission source used in e.g. SEM or STEM. The form of the aberration at each energy is cubic, indicating that that geometric aberrations have been corrected to the second-order. The RMS value of the probe radius at the 10 keV energy is around 2 nm.

As will be appreciated by a person skilled in the art, when forming an electron probe from an objective lens, there are certain parameters that will be selected according to the application, such as working distance (distance from lens pole-piece to specimen), the aperture size, which will be used to provide a certain probe current for a give spatial resolution, characterised by the semi-angular spread at the specimen. Once these parameters have been decided, there is a systematic way of arriving at the second-order minimum geometric aberration condition according to example embodiments, maintaining parameters like the target working distance. In one embodiment, the voltages on the plates of the core-lenses 801 to 803 are systematically optimised by noting how the final probe size varies with final semi-angular spread in the simulation. If there is a linear dependence, the voltages are varied in a way that reduces it. Around where its gradient changes sign, a parabolic dependence is found. The process is then repeated, varying the voltages slightly until the curvature of the parabolic dependence changes sign, until a cubic dependence is obtained. This can be achieved in the simulation, for example using the converging-diverging-converging combination in the 3 stage corrector structure 804 (for an incoming diverging beam in an example embodiment). This enables to find the second-order aberration focusing condition according to example embodiments, and the resolution of the final probe will depend on parameters like the type of objective lens used, the working distance, the system demagnification, and semi-angular spread at the specimen. In practical applications, the process may be done more indirectly, by adjusting the voltages until a minimum resolution in the image is obtained.

FIG. 10 compares the simulated geometric aberration for the corrected annular beam according to an example embodiment with that of the comparable case where a hole-aperture is used with the same objective lens for the same probe current (same cross-sectional aperture area). The focal point is taken at a place where the simulated probe radius is a minimum. The predicted probe root means square (RMS) radius for the comparable hole-aperture column (see section A of the graph in FIG. 10) is around 50 times bigger than for the second-order corrected annular focused beam (see section B of the graph in FIG. 10). FIG. 10 shows that chromatic aberration is the dominant aberration for the corrected focused annular beam case (see section B of the graph in FIG. 10), whereas for the uncorrected hole-aperture focused beam, it is geometric aberration (see section A of the graph in FIG. 10). The angular spread in the annular focused beam case (see section B of the graph in FIG. 10) is much smaller than the angular spread of the hole-aperture beam case (see section A of the graph in FIG. 10), despite the latter having the same beam current as the former. This is found to be possible because the ring shape of the annular aperture has a much smaller width than the radius of the hole-aperture for the same effective beam passing area. It is found to be this property that gives rise to the better predicted spatial resolution size of the annular focused beam, since after geometric aberration correction of the annular focused beam, both beams are characterised by third-order geometric aberrations. These simulation results predict that there is a considerable advantage to be gained by transforming a conventional focused electron/ion beam column to function as an annular focused beam one, and utilising a second-order geometric aberration correction system according to example embodiments to minimise the final probe size. The radii for the apertures are R0=75.65 μm for the circular aperture and R1=132.77 μm and R2=152.81 μm for the annular aperture. The RMS probe radii are 97 nm and 2 nm respectively for the uncorrected circular beam case and annular beam corrected case, according to an example embodiment.

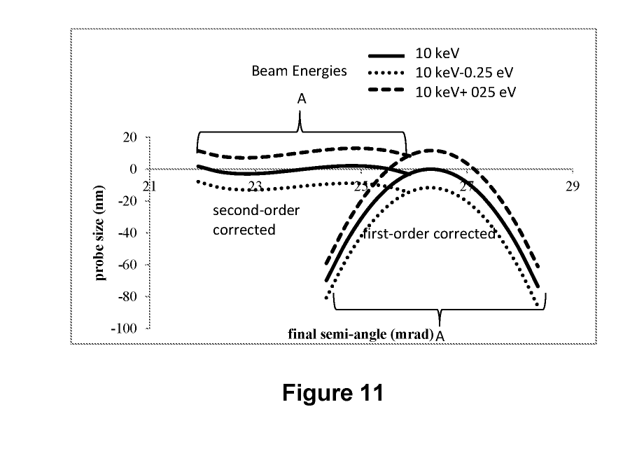

FIG. 11 compares the simulated probe size at the second-order annular beam focusing condition according to an example embodiment (see section A of the graph in FIG. 11) to an existing first-order corrected case (see section B of the graph in FIG. 11). It demonstrates that the geometric aberration variations at the second-order condition according to example embodiments (see section A of the graph in FIG. 11) were found to be typically over one order of magnitude smaller than for the first-order corrected case (see section B of the graph in FIG. 11), illustrating the significant improvement of the core-lens corrector system according to example embodiments. As can be seen form FIG. 11, if only first-order geometric aberration is corrected, the RMS probe radius is 40 nm, achieved with a single core lens at V=−3.16 V, whereas 2 nm is achieved for the annular beam corrected case, according to an example embodiment.

| | | | Einzel | RMS | | |
|---|---|---|---|---|---|---|
| | | | lens | probe | Total | |
| | Aperture | | focusing | radius | weighted | |
| | radii | | voltage | (nm) | probe | |
| | (μm) | | V_{F} (kV) | within | radius | |
| | for the | | for | ±2 mrad | including | |
| | same | Core- | working | of final | chromatic | |
| | amount | lens | distance | semi- | aberration | Diffraction |
| 10 kV | of probe | voltages | of 5.25 | angular | for ΔE = | radius |
| column | current | (V) | mm | spread | ±0.25 eV | (nm) |
| Circular | R₀ = | N.A. | 29.8 | 97.2 | 97.3 | 0.3 |
| focused | 75.65 | | | | | |
| beam | | | | | | |
| First- | R₁ = | V = −3.16 | 29.43 | 38.3 | 38.7 | Coherent: |
| order | 132.21 | | | | | 0.9 |
| annular | R₂ = | | | | | Incoherent: |
| focused | 153.35 | | | | | 1.9 |
| Second- | R₁ = | V₁ = −37 | 29.3 | 2.0 | 6.4 | Coherent: |
| order | 132.77 | V₂ = 37 | | | | 1.0 |
| annular | R₂ = | V₃ = | | | | Incoherent: |
| focused | 152.81 | −7.38 | | | | 1.9 |

Table 1 summarises the simulated geometric aberration probe radii for an existing first-order case and for second-order corrected annular focused beams according to example embodiments, together with the comparable hole-aperture focused beam (for the same probe current). Table 1 also gives an estimate of the combined geometric-chromatic aberration radius by forming a weighted average of the geometric aberration RMS radius over energy, where the weight at the central energy (10 keV) is twice the weight for the other two energies (10 keV −0.25 eV and 10 keV+0.25 eV). These results confirm that for the second-order corrected annular focused beam according to example embodiments, the combined geometric-chromatic aberration radius estimate is dominated by chromatic aberration, while for the comparable hole-aperture focused beam, it is dominated by geometric aberration. While for higher relative energy beam spreads (at say lower beam energies), the advantage of the corrected annular focused beam will be reduced, some form of chromatic aberration corrector can additionally be used in different embodiments, for example the design of a chromatic corrector for annular focused beams based upon the use of superimposed magnetic and electric core lens fields described in [7].

Table 1 also gives estimates of the diffraction limited probe radius, calculated for incoherent and coherent emission. For a field emission source, diffraction aberration is usually coherent, whereas for thermionic emission, it is usually incoherent. For incoherent emission, the diffraction aberration probe radius can be estimated by the usual formula 0.3λ/Δθ, where λ is the de Broglie wavelength and Δθ is the angular spread at the specimen.

An approximate estimate of the diffraction aberration at radius r at the focal plane for coherent emission, M(r), with wavenumber k for a ring aperture having radii Rₐ₁ and Rₐ₂ projecting semi-angles θ₁ and θ₂ can be estimated by using the Fraunhofer formula for circular shaped apertures,

$$M ( r ) = \frac{M ( 0 )}{( 1 - {ɛ}^{2} )} [ \frac{2 {J}_{1} ( {X}_{2} )}{{X}_{2}} - \frac{2 {J}_{1} ( {X}_{1} )}{{X}_{1}} {ɛ}^{2} ]$$

where M(0) is the diffraction pattern value on the axis (r=0), J₁ is the Bessel function of the first kind, order 1, ε=Rₐ₁/Rₐ₂, X₂=k r sin θ₂, and X₁=k r sin θ₁ [9].

This function can be transformed into a normalised intensity pattern [M(r)/M(0)]² and integrated as a function of radius to estimate the diffraction radius which contains 50% of the total current. As the ring width decreases, more of the current is transferred to the outer fringes. On the other hand, the diffraction radius decreases with average semi-angle, and in practice, a compromise needs to be found between deceasing the ring width to lower the chromatic and spherical aberrations, while at the same time enlarging it to obtain sufficient current and prevent diffraction aberration from becoming too large. The calculated values shown in Table 1 show that the coherent diffraction at the beam energy of 10 keV is not expected to be significant for the annular focusing beam conditions for the simple test example analysed here. The coherent diffraction aberration radius is predicted to be around half its incoherent aberration value, and is over six times smaller than the simulated combined geometric-chromatic aberration for the second-order corrected annular focused beam according to example embodiments.

In one embodiment, a corrector structure for correcting aberration of an annular focused charged-particle beam is provided, the corrector structure comprising a plurality of lenses configured for reducing second-order geometric aberration in the charged-particle beam.

The lenses may comprise core-lenses.

The lenses may comprise at least one converging lens and at least one diverging lens.

For a charged-particle beam converging from a source in a direction towards an objective lens, the corrector structure may comprise two or more lenses.

For a charged-particle beam diverging from a source in a direction towards an objective lens, the corrector structure may comprise three or more lenses.

The lenses may comprise two converging lenses and one diverging lens. The diverging lens may be disposed between the two converging lenses along a path for the charged-particle beam.

The corrector structure may be configured for disposal between an objective lens and an annular aperture along a path for the charged-particle beam.

The lenses, ay comprise electric field, magnetic field and/or combined electric/magnetic field lenses.

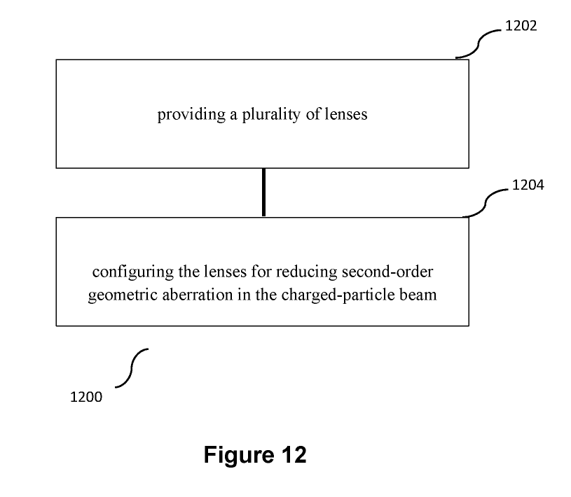

FIG. 12 shows a flow chart illustrating a method 1200 for correcting aberration of an annular focused charged-particle beam, according to an example embodiment. At step 1202. a plurality of lenses is provided. At step 1204, the lenses are configured for reducing second-order geometric aberration in the charged-particle beam.

The lenses may comprise core-lenses.

The lenses may comprise at least one converging lens and at least one diverging lens.

For a charged-particle beam converging from a source in a direction towards an objective lens, the corrector structure may comprise two or more lenses.

For a charged-particle beam diverging from a source in a direction towards an objective lens, the corrector structure may comprise three or more lenses.

The lenses may comprise two converging lenses and one diverging lens. The method may comprise disposing the diverging lens between the two converging lenses along a path for the charged-particle beam.

The method may comprise disposing the corrector structure between an objective lens and an annular aperture along a path for the charged-particle beam.

The lenses may comprise electric field, magnetic field and/or combined electric/magnetic field lenses.

In one embodiment, a column for focusing a charged particle beam is provided, comprising a corrector structure for correcting aberration of an annular focused charged-particle beam, the corrector structure comprising a plurality of lenses configured for reducing second-order geometric aberration in the charged-particle beam.

### INDUSTRIAL APPLICATION

The system and method of correcting geometric aberrations up to second-order in charged particle annular focused beam optics according to the example embodiments described herein are predicted to have over 50 times smaller final geometric aberration limited spot sizes than a conventional comparable hole-aperture focused beam having the same probe current. This makes example embodiments of the present invention of interest to applications such as SEM, STEM, transmission electron microscopy (TEM), focused Ion beams such as e.g. in Helium Ion Microscopes and Electron Beam Spectroscopy and also in electron beam lithography where a high probe current needs to be combined with high spatial probe resolution.

For example, the system and method according to example embodiments can be useful for 100 to 300 kV scanning electron microscopes that are used for E-Beam Lithography and Scanning Transmission Electron Microscopy (STEM). They may be also useful for Scanning Electron Microscopes (SEMs), in particular those using energy monochromators.

The system and method according to example embodiments can preferably allow for the combination of high probe current with high spatial resolution in situations, in particular where chromatic aberration is low, where the relative energy spread may typically be below 2×10⁻⁵.

It will be appreciated by a person skilled in the art that numerous variations and/or modifications may be made to the present invention as shown in the specific embodiments without departing from the spirit or scope of the invention as broadly described. The present embodiments are, therefore, to be considered in all respects to be illustrative and not restrictive. Also, the invention includes any combination of features, in particular any combination of features in the patent claims, even if the feature or combination of features is not explicitly specified in the patent claims or the present embodiments.

For example, while electric field corrector lenses and objective lenses have been used in the described embodiments, electric field, magnetic field and or a combination of electric and magnetic fields corrector lenses and objective lenses can be used in different embodiments.

Also for example, while variation of the voltages of electric field corrector lenses has been used in the described embodiments, one or more of the electric field, the magnetic field, and a combination of electric and magnetic fields can be varied in different embodiments to achieve the correction for 2^{nd} order aberration of the annular focused charged-particle beam.

Also for example, while a single objective lens has been corrected in the described embodiments, the present invention can also be applied to the correction of a column of multiple objective lenses in different embodiments.

### REFERENCES

[1] F. Lenz and A. P. Wilska, Optik 24 (1966/67) 383.
[2] E. Plies, Nuclear Instruments and Methods 187 (1981) 217-226.
[3] Nuclear Instruments and Methods 187 (1981) 217-226.
[4] H. Ito, Y. Sasaki, T. Ishitani, Y. Nakayama, U.S. Pat. No. 7,947,964 B2, May 24, 2011.
[5] A. Takaoka, R. Nishi and H. Ito, Optik, 126 (2015) 1666-1671.
[6] A. Khursheed, Ultramicroscopy 128 (2013) 10-23.
[7] A. Khursheed and W. K. Ang, Microscopy and Microanalysis 21(S4):106-111 ⋅ June 2015.
[8] LORENTZ-2EM, Integrated Engineering Software Inc., Canada.
[9] JCH Spence in “High-Resolution Electron Microscopy”, (Oxford University Press) p. 80.

1. A corrector structure for correcting aberration of an annular focused charged-particle beam, the corrector structure comprising a plurality of lenses configured for reducing second-order geometric aberration in the charged-particle beam.

2. The corrector structure of claim 1, wherein the lenses comprise core-lenses.

3. The corrector structure of claim 1, wherein the lenses comprise at least one converging lens and at least one diverging lens.

4. The corrector structure of claim 1, wherein for a charged-particle beam converging from a source in a direction towards an objective lens, the corrector structure comprises two or more lenses.

5. The corrector structure of claim 1, wherein for a charged-particle beam diverging from a source in a direction towards an objective lens, the corrector structure comprises three or more lenses.

6. The corrector structure of claim 1 wherein the lenses comprise two converging lenses and one diverging lens.

7. The corrector structure of claim 6, wherein the diverging lens is disposed between the two converging lenses along a path for the charged-particle beam.

8. The corrector structure of claim 1, wherein the corrector structure is configured for disposal between an objective lens and an annular aperture along a path for the charged-particle beam.

9. The corrector structure of claim 1, wherein the lenses comprise electric field, magnetic field and/or combined electric/magnetic field lenses.

10. A method for correcting aberration of an annular focused charged-particle beam, the method comprising:
providing a plurality of lenses; and
configuring the lenses for reducing second-order geometric aberration in the charged-particle beam.

11. The method of claim 10, wherein the lenses comprise core-lenses.

12. The method of claim 10, wherein the lenses comprise at least one converging lens and at least one diverging lens.

13. The method of claim 10, wherein for a charged-particle beam converging from a source in a direction towards an objective lens, the corrector structure comprises two or more lenses.

14. The method of claim 10, wherein for a charged-particle beam diverging from a source in a direction towards an objective lens, the corrector structure comprises three or more lenses.

15. The method of claim 10, wherein the lenses comprise two converging lenses and one diverging lens.

16. The method of claim 15, comprising disposing the diverging lens between the two converging lenses along a path for the charged-particle beam.

17. The method of claim 10, comprising disposing the corrector structure between an objective lens and an annular aperture along a path for the charged-particle beam.

18. The method of claim 10, wherein the lenses comprise electric field, magnetic field and/or combined electric/magnetic field lenses.

19. A column for focusing a charged particle beam, comprising the corrector structure of claim 1.
